(19) United States
(12) Patent Application Publication
(10) Pub. No.: US 2017/0160331 A1
(43) Pub. Date: Jun. 8, 2017

(54) CABLE TESTING DEVICE AND METHOD

(71) Applicant: ORMAZABAL Y CIA, S.L.U., Igorre (Bizkaia) (ES)

(72) Inventors: Juan M CASADO CARTÓN, Igorre (Bizkaia) (ES); José Luis SABAS FERNANDEZ, Igorre (Bizkaia) (ES)

(21) Appl. No.: 15/324,523

(22) PCT Filed: Jul. 10, 2014
(86) PCT No.: PCT/ES2014/070567

§ 371 Date: Jan. 6, 2017

(51) Int. Cl. G01R 31/02; H02B 11/28; G01R 31/327; G01R 31/12; H02B 13/075

(52) U.S. Cl. CPC G01R 31/021; G01R 31/1272; H02B 13/075; G01R 31/3274; H02B 11/28

(57) ABSTRACT

A cable testing device (6) integrated in high-voltage electrical equipment (3) provided with a main circuit (17), including at least one line connection (4) and one cable outlet (5); at least one control means comprising at least one switch (1a) and/or one disconnecting switch (1b, 1c, 1d). The testing device (6) stands out as it is installed as a first element upstream of the cable outlet (5) and at the same time downstream of the switch (1a) and/or of the disconnecting switch (1b)(1c)(1d), the testing device (6) being independent from the operation of the main circuit (17), such that the switch (1a) and/or the disconnecting switch (1b)(1c)(1d) keep their contacts in an open position during cable testing, the voltage to perform cable testing being injected into the cable outlet (5) through the testing device (6).

### OBJECT OF THE INVENTION

The present invention belongs to the field of power distribution and transformation; and more specifically to cable testing systems in power distribution networks.

The object of the present invention is a cable testing device that can be integrated in high-voltage electrical equipment and allows performing cable testing safely without having to use any auxiliary tool or accessing active parts of the main circuit. It also and allows performing said cable testing where the elements of the main circuit are kept inactive, i.e., they have no voltage when performing said testing, and where the conditions of the switchgear do not change, such as the ground connection, with respect to that which has been supplied by the manufacturer or verified during initial installation. Likewise, the object of the invention is to provide a testing method for testing cables which is carried out by means of the mentioned testing device and wherein said testing device is kept inactive during the normal operation (service) of high-voltage electrical equipment.

### BACKGROUND OF THE INVENTION

Cables in power distribution networks require periodic testing consisting of checking the insulation resistance of cables and their connections, using to that end cable testing equipment, the purpose of which is to ascertain that there is no fault between the system elements, which is produced during system cable and accessory installation, or during normal operation. To perform said cable testing, this cable testing equipment is connected in power distribution facilities, for example, in power transformation centers, distribution centers, sub-stations, etc., and specifically in high-voltage electrical equipment also known as switchgear.

More particularly, cable testing can be performed by means of “external” testing systems or by means of systems “integrated” in the switchgear itself.

An “external” testing system requires accessing the compartment of the cables of a switchgear and connecting the testing equipment to the cables of the power grid, which entails the need to access the connectors of the cables and to handle said connectors. These actions have the drawbacks of having to use auxiliary tools for disassembling/assembling the cables and their connectors, requiring specific tools to perform said cable testing, having to depend on more qualified staff to perform said actions, as well as changing the connections and insulations that were originally installed.

In turn, the “integrated” cable testing systems comprise a connection point integrated in the switchgear itself, where the cable testing equipment is connected. This testing equipment is connected with the cables of the power grid through said connection points, such as bushings, for example, that can be arranged inside a separate compartment and interlocked with the disconnecting grounding switch or can be accessed without any type of interlocking available. Generally, these bushings are the same as those used for grounding the three phases of the switchgear. This means that when said switchgear is in service, the bushings of the three phases are connected to one another by an external and accessible conductor which is in turn attached to the ground of the facility, providing the switchgear disconnecting grounding switch with the ground connection required by the applicable regulation and safety conditions.

When there are such bushings in the switchgear, cable testing can usually be performed according to the following method:

a) Closing the disconnecting grounding switch once the absence of voltage in the main circuit is verified.

b) Opening the cover of the cable testing compartment (if there is a cover).

c) Connecting the cable testing equipment to the bushings.

d) Removing the detachable grounding bridge which short-circuits the bushings.

e) Performing cable testing by injecting the corresponding voltage.

f) Placing the detachable grounding bridge again, short-circuiting the cable testing bushings.

g) Disconnecting and removing the cable testing equipment.

h) Closing the cover of the cable testing compartment (if there is a cover).

i) Opening the disconnecting grounding switch.

Like the external testing system, this integrated testing system also requires qualified staff to perform cable testing, and safety also depends mainly on operators correctly performing said testing, since whether or not the steps of the previously mentioned method are correctly executed in the indicated order depends on said operators, particularly in the case in which cable testing is not compartmentalized or interlocked.

The detachable grounding bridge short-circuits the cable testing bushings when the switchgear is in service. For testing cables said detachable grounding bridge must be removed, but removing the detachable bridge before connecting the cable testing equipment to the bushings involves accessing the active parts which can be electrically connected, and the only safety measure (grounding the bushings) has been removed. Furthermore, it must be taken into account that the conditions of the electrical equipment supplied and tested by the manufacturer and the initial installation conditions are changing and must be re-established every time cable testing is performed. In this sense, examples such as those defined in patent documents EP0054726 and DE4121764 can be mentioned.

In order to avoid this risk situation, there are other types of solutions, such as that defined in international patent application with publication number WO2011073418A1, for example. This solution relates to medium voltage switchgear comprising a metal enclosure provided with a connection point for connecting the cable testing equipment. This connection point is located upstream of the disconnecting switch and of the switch of the main circuit, and as a first element downstream of the connection busbar of the switchgear. The connection point internally comprises a cable test contact which is in turn the contact for grounding the disconnecting switch of the main circuit. Likewise, said connection point has a grounding element which can ground the cable test contact and extends between said contact and the outer part of the connection point (outside the enclosure of the switchgear). This grounding element is grounded through the metal enclosure of the switchgear. When the switchgear is in service, the grounding element is attached to the cable test contact, so the latter is at ground potential.

When performing cable testing and once the absence of voltage in the main circuit is verified, the disconnecting switch of the main circuit is closed with respect to the ground contact (cable test contact). The main circuit is thus grounded. The grounding element has a hollow configuration, such that the electrode of the testing equipment is introduced through same until it is connected with the test contact. Therefore, the testing equipment is electrically connected with the cables to be tested through the test contact, the disconnecting switch and the switch of the main circuit. Once the electrode of the testing equipment is connected with the test contact, the grounding element is removed by pulling it out, thus disconnecting the test contact from ground potential. In this situation, the facility would be ready to perform cable testing.

As a safety measure the preceding solution comprises an interlocking between the grounding element and the disconnecting switch and switch of the main circuit, such that only the introduction of the electrode of the testing equipment and the subsequent removal of the grounding element (disconnecting the grounding element from the test contact) are allowed when the main switch is in a connected position and the disconnecting switch of the main circuit is in a grounded position (attached to the cable test contact).

In the preceding solution, all the elements of the main circuit participate in cable testing, i.e., the disconnecting switch and the main switch are subjected to the voltage injected for cable testing. In summary, given that the connection point for the testing equipment is located upstream of the elements of the main circuit, said testing equipment is electrically connected with the cables to be tested through the test contact, the disconnecting switch and the switch of the main circuit.

The participation of the switch and of the disconnecting switch of the main circuit in cable testing means that they must tolerate the voltage applied for cable testing. Furthermore, given that the connection point for the cable testing equipment is located upstream of the disconnecting switch and of the switch of the main circuit and as a first element downstream of the connection busbar of the switchgear, the contiguous switchgear must also tolerate said voltage when the cable testing voltage is applied.

Patent ES2401120T3 also relates to switchgear with a cable testing device. In this solution the switchgear also comprises different elements in the main circuit, such as a switch or load break switch and a disconnecting grounding switch, for example. Like in the preceding case, in this case the disconnecting grounding switch also participates in cable testing, through which the cable testing equipment is electrically contacted with the cables to be tested.

Both in the case of WO2011073418A1 and ES2401120T3, the cable testing device itself is the grounding element of the main circuit, such that the main circuit is grounded through a grounding collector incorporated in the cable testing device itself. In summary, the cable testing device is not an element independent from the main circuit, since neither the elements of the main circuit (switch and disconnecting grounding switch) nor the cable testing device are inactive during cable testing and when the switchgear is in service, respectively. Furthermore, it is necessary to disconnect the main circuit from the ground to perform cable testing, and therefore the conditions of the electrical equipment supplied and tested by the manufacturer as well as the initial installation conditions are modified, this involving the need to restore the initial conditions every time cable testing is performed.

### DESCRIPTION OF THE INVENTION

The present invention solves the drawbacks mentioned above by providing a cable testing device which is applicable in power distribution networks and integrated in high-voltage electrical equipment also known as switchgear.

The cable testing device object of invention is installed together with the elements of the main circuit of the electrical equipment between at least one line connection and at least one cable outlet, specifically as a first element upstream of at least one cable outlet and at the same time downstream of at least one control means, such as a switch and/or one disconnecting switch, for example.

More particularly, the testing device described herein is a device independent from the operation of the main circuit but interlocked with the actuation of the switch and/or disconnecting switch of the main circuit. In other words, the testing device is kept inactive (in a grounded position) when switchgear is in service or normal operation and the elements of the main circuit (switch, disconnecting switch, etc.) are kept inactive (the contacts are in an open or grounded position, without the possibility of connecting the main circuit) when performing cable testing, such that the switch and/or the disconnecting switch do not tolerate the voltage applied for cable testing, said voltage being injected into the cable outlet through the testing device. The non-participation of the elements of the main circuit therefore reduces and segregates the dielectric loads that high-voltage electrical equipment must tolerate.

The testing device of the invention preferably additionally comprises at least one inlet with at least one contact where the cable testing equipment is connected, and through where the voltage for performing the test is applied. Likewise, the inlet of the testing device comprises at least a first part made of an insulating material, which incorporates the contact for the connection of the cable testing equipment at least partially therein.

Furthermore, the possibility of the inlet of the testing device additionally comprising a second part made of an insulating material which is concentric to and slides with respect to the first part and incorporates the contact for the connection of the cable testing equipment at least partially therein is contemplated. This second sliding part made of an insulating material provides greater dielectric distance between electrically connected active parts and parts connected to ground potential.

On the other hand, the possibility of the testing device being able to additionally comprise at least one moving contact inside the electrical equipment, electrically connected with the contact for the connection of the cable testing equipment and moving between a grounded position and an output cable-connected position is contemplated. In the output cable-connected position, the moving contact is in electrical contact with at least one phase of the cable outlet of the switchgear, whereas in the grounded position, the moving contact is in electrical contact with at least one flange which is grounded. In this sense, the testing device is grounded in its grounded position, i.e., it is connected to ground potential when the switchgear is in service. In the output cable-connected position, the testing device is connected to the same potential as the phases of the cable outlet of the switchgear, cable testing being performed in this position by applying the corresponding voltage in said phases through the testing device, the elements of the main circuit remaining inactive since the contacts of the switch and/or of the disconnecting switch located upstream have been previously opened, such that reliable insulation between the power grid line connection and the cable outlet of the switchgear is obtained during cable testing.

According to a preferred embodiment, the moving contact of the testing device moves integrally with a platform which preferably comprises at least one transmission system, such that the actuation of said transmission system causes the movement of the platform and in turn the movement of the moving contact between the grounded position and the output cable-connected position of the testing device. The transmission system comprises at least one drive shaft and at least one lever.

Therefore, the movement of the moving contact of the testing device is produced by means of actuating this lever. The testing device of the invention therefore allows performing cable testing without having to use auxiliary tools and without having to depend on qualified staff. Furthermore, since it is not necessary to access the active parts of the facility, making changes in the conditions of the high-voltage electrical equipment supplied and tested by the manufacturer as well as in the initial installation conditions are prevented. In summary, operational safety for carrying out cable testing is increased.

More preferably, the lever comprises at least one projection which is fitted into the first parts made of an insulating material of the testing device in the output cable-connected position (testing device connected with at least one phase of the cable outlet) and the grounded position (testing device grounded) of the testing device, thus preventing the rotation of the lever. The lever in turn comprises on one of its sides at least one through hole which in the output cable-connected position of the testing device allows access to the contacts for the connection of the cable testing equipment and on another one of its sides at least one dead wall which in the grounded position of the testing device prevents access to said contacts.

As another safety measure, it has been envisaged that the testing device can additionally comprise an interlocking with the disconnecting switch of the switchgear, such that in the grounded position of the testing device any operation of the disconnecting switch is prevented when at least one cover of the compartment of the testing device or of the compartment of the cables is open.

Another object of the invention which will be described below is a testing method for testing cables which is carried out by means of the testing device described above and comprises the following steps:

a) opening the contacts of the switch and/or the disconnecting switch;

b) closing the contacts of the disconnecting switch in a grounded position once the absence of voltage in the circuit is verified;

c) opening the cover of the compartment of the testing device or of the compartment of the cable outlet, putting the switch and/or disconnecting switch into service being restricted by interlocking;

d) actuating the testing device from the grounded position to the output cable-connected position;

e) connecting cable testing equipment to the at least one inlet of the testing device; and

f) opening the contacts of the disconnecting switch, said disconnecting switch being in the position of disconnection.

Likewise, once cable testing has been performed according to the steps of the preceding paragraph, the method for putting the corresponding high-voltage electrical equipment back in service comprises the steps of:

g) grounding the contacts of the disconnecting switch;

h) disconnecting the cable testing equipment from the at least one inlet;

i) actuating the testing device from the output cable-connected position to the grounded position;

j) closing the cover of the compartment of the testing device or of the compartment of the cables, thus releasing the disconnecting switch; and

k) closing the contacts of the switch and/or the disconnecting switch in the position of connection, the high-voltage electrical equipment thus being operative.

### DESCRIPTION OF THE DRAWINGS

To complement the description that is being made and for the purpose of aiding to better understand the features of the invention according to a preferred practical embodiment thereof, a set of drawings is attached as an integral part of said description in which the following is depicted with an illustrative and non-limiting character:

FIG. 1A shows a perspective view of the cable testing device of the invention according to a first preferred embodiment, said testing device being depicted in a grounded position.

FIG. 1B shows a perspective view of the testing device in an output cable-connected position.

FIG. 2 shows a front view of the cable testing device of FIG. 1B.

FIG. 3 shows a plan view of the cable testing device.

FIG. 4 shows another perspective view of the testing device where its grounding flanges are shown.

FIG. 5 shows a perspective view of the testing device according to a second preferred embodiment in which the cable testing equipment is connected through at least one conductor.

FIG. 6 shows a single-line diagram of electrical equipment incorporating the cable testing device of the invention.

FIG. 7 shows a general perspective view of electrical equipment in which the testing device of the invention is incorporated.

FIG. 8 shows a perspective view of the testing device according to the second preferred embodiment in which the cable testing equipment is connected through at least one point of contact.

### PREFERRED EMBODIMENT OF THE INVENTION

Several preferred embodiments are described below in relation to the aforementioned drawings without it limiting or reducing the scope of protection of the present invention.

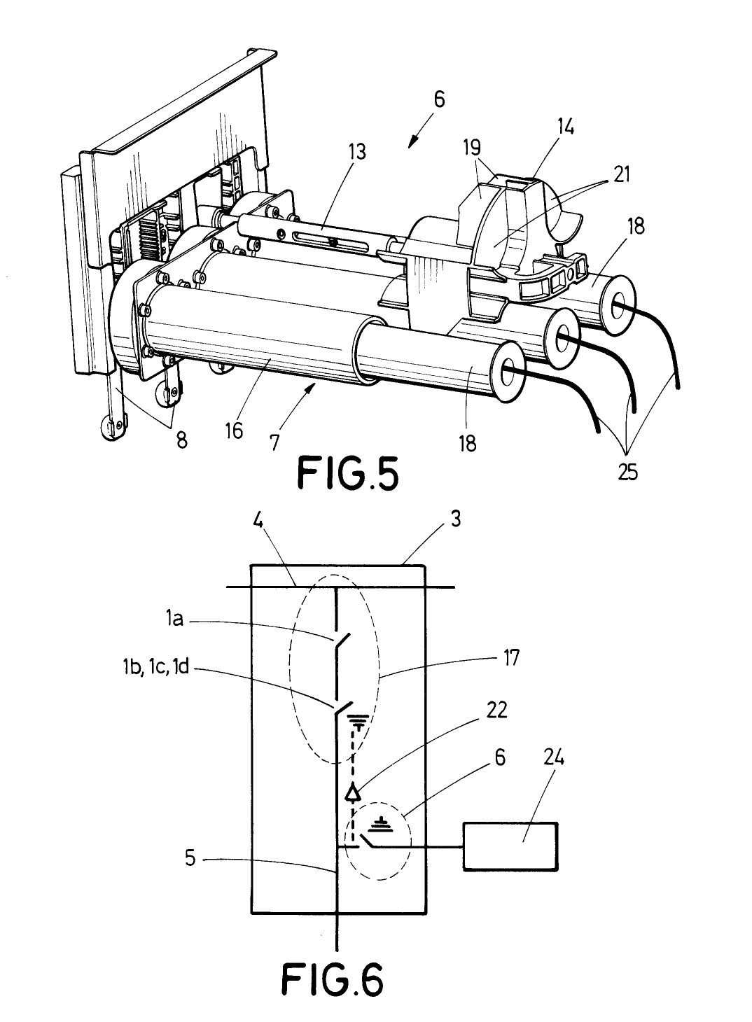

According to a possible practical embodiment of the invention, the drawings show a cable testing device (6) which is incorporated in high-voltage electrical equipment (3) also known as switchgear. The testing device (6) object of the invention is a passive element, i.e., during normal operation of the electrical equipment (3) said testing device (6) is kept inactive (it is kept in a grounded position), whereas the control means of the main circuit (17) (the switch (1a) and/or the disconnecting switch (1b, 1c, 1d)), schematically shown in FIG. 6, are active (a current circulates through same). In contrast, during cable testing the control means (1a, 1b, 1c, 1d) are kept inactive (their contacts are kept in an open or grounded position). In summary, the testing device (6) of the invention is a device independent from the operation of the main circuit (17), i.e., it is not linked with the control means (1a, 1b, 1c, 1d) when the electrical equipment (3) is in service, and in turn the control means (1a, 1b, 1c, 1d) are also not linked with the testing device (6) during cable testing.

As shown in FIG. 6, the testing device (6) of the invention is installed together with the elements of the main circuit (17) of the electrical equipment (3) between at least one line connection (4) and at least one cable outlet (5), specifically as a first element upstream of the at least one cable outlet (5) and at the same time downstream of at least one control means (1a, 1b, 1c, 1d), such as a switch (1a) and/or a disconnecting switch (1b, 1c, 1d), for example.

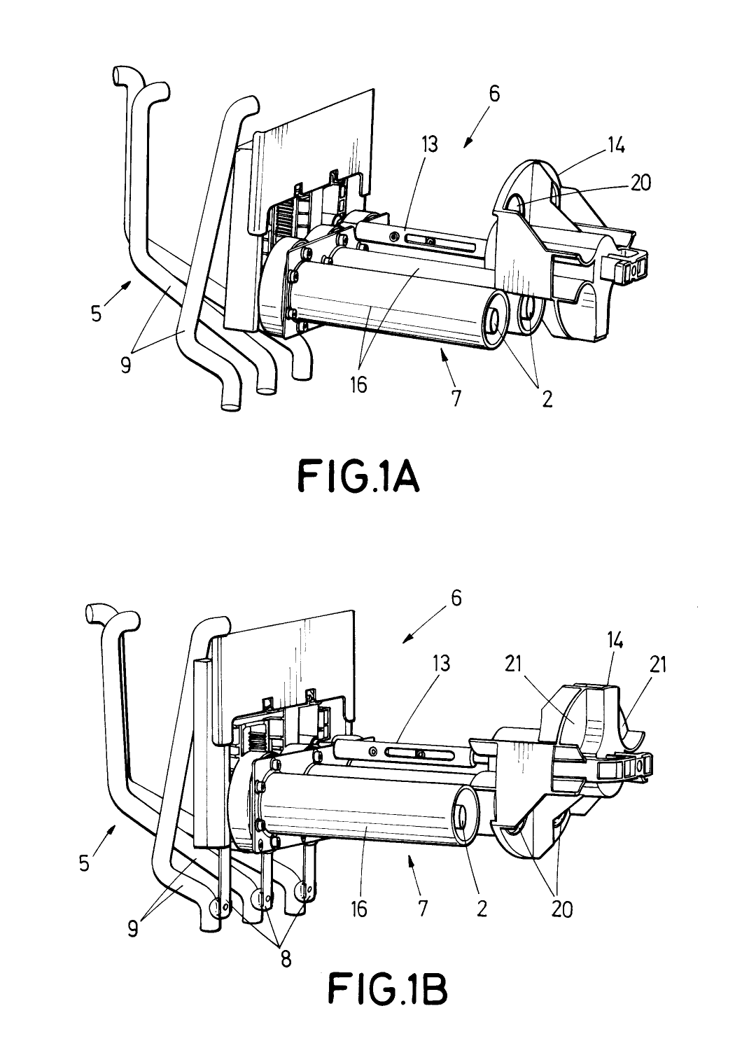

According to a first preferred embodiment shown in FIGS. 1 to 4, the testing device (6) comprises at least one inlet (7) with at least one contact (2) where the cable testing equipment (24) is connected, and through which the voltage to perform the test is applied. Likewise, the inlet (7) of the testing device (6) comprises at least a first part (16) made of an insulating material which incorporates the contact (2) for the connection of the cable testing equipment (24) at least partially therein.

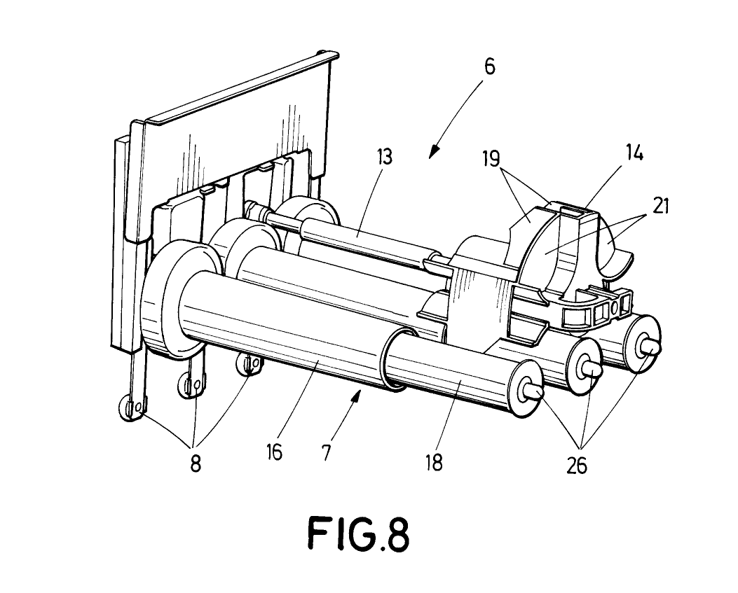

In a second preferred embodiment of the invention shown in FIGS. 5 and 8, the possibility of the inlet of the testing device (6) being able to comprise a second part (18) made of an insulating material which is concentric to and slides with respect to the first part (16) and incorporates the contact (2) for the connection of the cable testing equipment (24) at least partially therein either through at least one conductor (25) or through at least one point of contact (26) is contemplated. This sliding second part (18) made of an insulating material provides greater dielectric distance.

In both possible embodiments, the testing device (6) of the invention comprises at least one moving contact (8), shown in FIGS. 1B, 2, 4, 5 and 8, which is electrically connected with the contact (2) for the connection of the cable testing equipment (24). This moving contact (8) moves integrally with a platform (10) and on the inside of the electrical equipment (3), depicted in FIG. 4, between a grounded position and an output cable-connected position. In the grounded position of the testing device (6), the moving contact (8) is grounded through a flange (15), shown in FIG. 4, whereas in the output cable-connected position of the testing device (6), the moving contact (8) is electrically connected with at least one phase (9) of the cable outlet (5) and insulated from ground.

As shown in FIGS. 1A, 1B, 4, 5 and 8, the moving contact (8) of the testing device (6) moves integrally with a platform (10) which comprises at least one transmission system, such that the actuation of said transmission system causes the movement of the platform (10) and in turn the movement of the moving contact (8) between the grounded position and output cable-connected position of the testing device (6). The transmission system comprises at least one drive shaft (13) and at least one lever (14). Therefore, the movement of the moving contact (8) of the testing device (6) is produced by means of actuating said lever (14). Although it has been envisaged in the preferred embodiment of the invention that the actuation of the lever (14) is manual, said actuation can also be motorized.

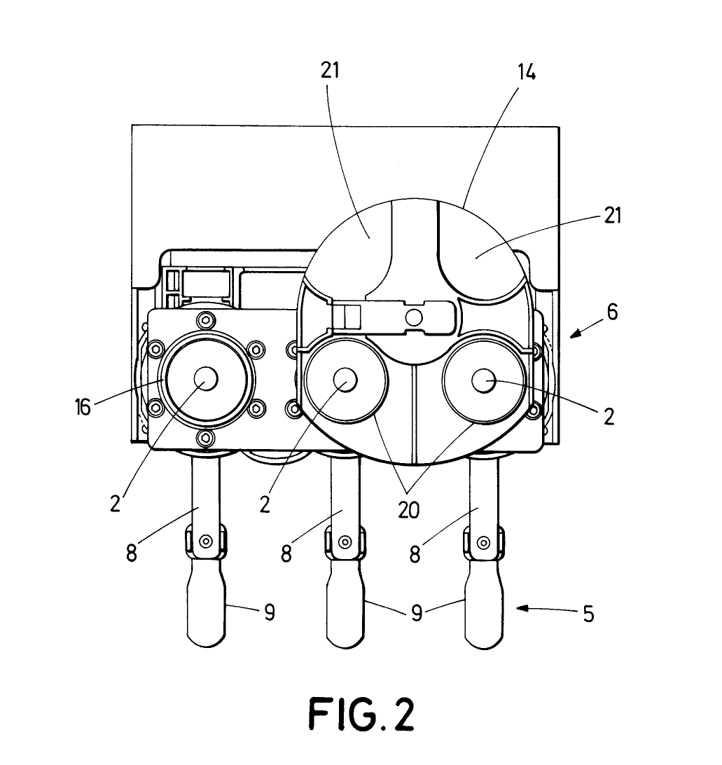

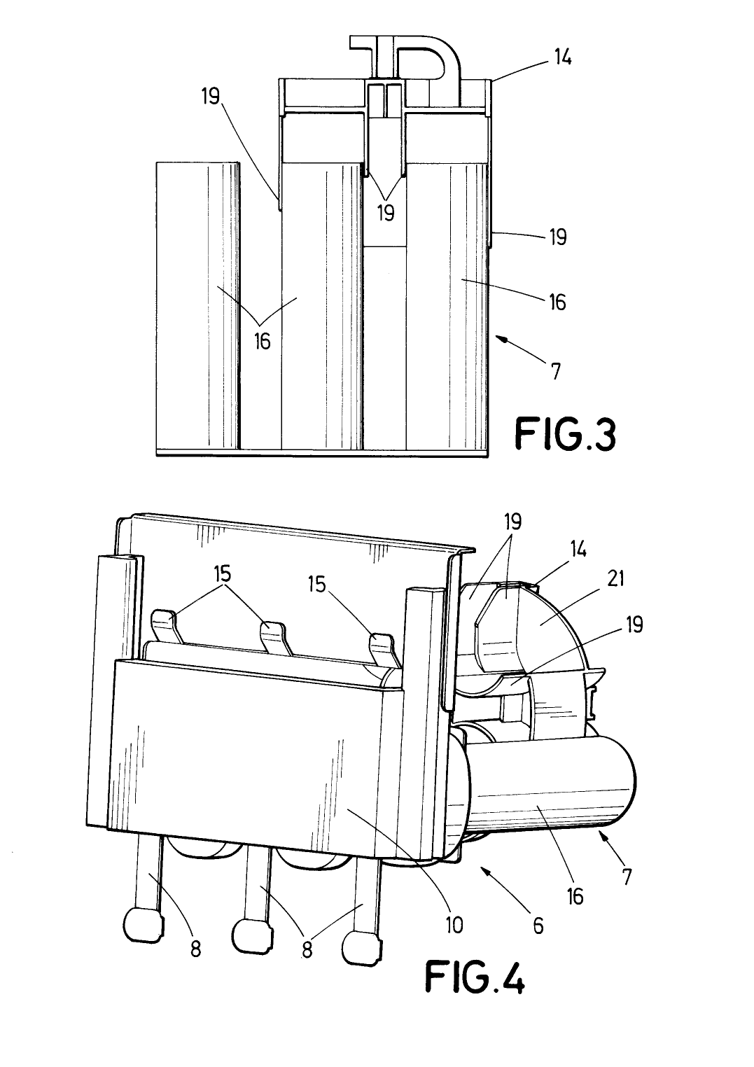

As a safety measure, as can be seen in FIGS. 3-5 and 8, the lever (14) comprises at least one projection (19) which is fitted into the first parts (16) of the testing device (6) in the output cable-connected and grounded positions of the testing device, thus preventing the rotation of the lever (14) when cable testing is being performed or when the electrical equipment (3) is in service or in normal operation. Likewise, the lever (14) comprises on one of its sides at least one through hole (20), shown in FIGS. 1A, 1B and 2, which in the output cable-connected position of the testing device (6), reflected in FIG. 1B, allows access to the contacts (2), and comprises on another one of its sides at least one dead wall (21) which, in the grounded position of the testing device (6) depicted in FIG. 1A, prevents access to said contacts (2).

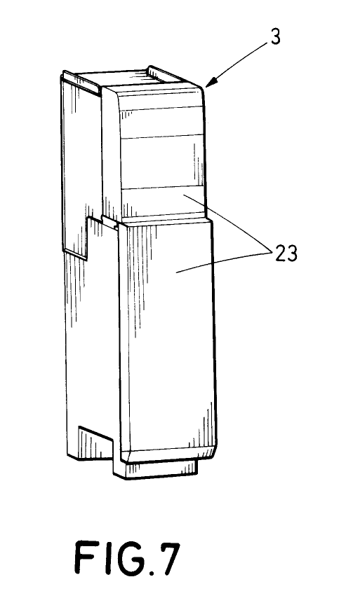

FIG. 6 shows a single-line diagram of an electrical equipment (3) wherein the testing device (6) comprises an interlocking (22) with the disconnecting switch (1b, 1c, 1d), such that in the grounded position of the testing device (6) all operations of the disconnecting switch (1b, 1c, 1d) are prevented when at least one cover (23) of the compartment of the testing device (6) or of the compartment of the cable outlet (5), see FIG. 7, is open.

The cable testing method using to that end the testing device (6) comprises several steps both for performing the test and for putting the electrical equipment (3) back in service after having performed said cable testing.

To perform cable testing, in a first step the contacts of the switch (la) and/or the disconnecting switch (1b, 1c, 1d) are opened, the main circuit (17) thus being inactive, i.e., without any power supply. In a second step, the contacts of the disconnecting switch (1b, 1c, 1d) are closed in a grounded position, such that all elements located downstream of said disconnecting switch (1b, 1c, 1d) are grounded. In a third step, the cover (23) of the compartment of the testing device (6) or of the compartment of the cable outlet (5) is opened, putting the switch (1a) and/or the disconnecting switch (1b, 1c, 1d) into service being restricted by interlocking in a safe position. In a fourth step, the testing device (6) is operated from the grounded position to the output cable-connected position, the moving contact (8) being in electrical connection with at least one phase (9) of the cable outlet (5) in this last position. In a fifth step, a cable testing equipment (24) is connected to the inlets (7) of the testing device (6), and finally in a sixth step the contacts of the disconnecting switch (1b, 1c, 1d) are opened, said disconnecting switch (1b, 1c, 1d) being in a position of disconnection and the facility is ready for cable testing.

Once cable testing is performed, the following steps are carried out to put the electrical equipment (3) back in service. In a first step, the contacts of the disconnecting switch (1b, 1c, 1d) are grounded, in a second step the cable testing equipment (24) is disconnected from the inlets (7), in a third step the testing device (6) is operated from the output cable-connected position to the grounded position, the moving contact (8) being in electrical connection with the grounding flange (15) of the testing device (6), in a fourth step the cover (23) of the compartment of the testing device (6) or of the compartment of the cables is closed, thus releasing the disconnecting switch (1b, 1c, 1d), and finally in a fifth step the contacts of the switch (1a) and/or the disconnecting switch (1b, 1c, 1d) are closed in the position of connection, the electrical equipment (3) thus being operative.

The electrical equipment (3) can comprise a switch (1a) and/or a disconnecting switch (1b, 1c, 1d), the switch (1a) being able to be a cut-off switch or a circuit breaker, and the disconnecting switch (1b, 1c, 1d) being able to be a disconnecting switch (1b), a disconnecting grounding switch (1c) or a disconnecting switch/disconnecting grounding switch (1d).

1. Cable testing device integrated in high-voltage electrical equipment provided with a main circuit which comprises:
at least one line connection and one cable outlet,
at least one control means installed between the line connection and the cable outlet, said control means comprising at least one switch (1a) and/or one disconnecting switch,
wherein the cable testing device comprises at least one inlet with at least one contact for the injection of cable testing voltage;
wherein said cable testing device is installed as a first element upstream of the cable outlet and at the same time downstream of the switch and/or of the disconnecting switch;
and wherein the testing device is independent from the operation of the main circuit, such that the switch and/or the disconnecting switch keep their contacts in an open position during cable testing, the voltage to perform cable testing being injected into the cable outlet through the testing device.

2. Testing device according to claim 1, wherein the inlet comprises at least a first part made of an insulating material incorporating the contact at least partially therein.

3. Testing device according to claim 2, wherein the inlet additionally comprises a second part made of an insulating material, which is concentric to and slides with respect to the at least first part and incorporates the contact at least partially therein.

4. Testing device according to claim 2, wherein the contact is connected with at least one moving contact that moves between a grounded position and an output cable-connected position of the testing device, said moving contact in the output cable-connected position being in electrical contact with a phase of the cable outlet.

5. Testing device according to claim 4, wherein the moving contact in the grounded position of the testing device is in electrical contact with at least one flange which is grounded.

6. Testing device according to claim 5, wherein the moving contact moves integrally with a platform.

7. Testing device according to claim 6, wherein the platform comprises at least one transmission system the actuation thereof causing the movement of the platform and in turn the movement of the moving contact between the grounded position and the output cable-connected position of the testing device.

8. Testing device according to claim 7, wherein the transmission system comprises at least one drive shaft and a lever, such that the actuation of the lever causes the movement of the moving contact.

9. Testing device according to claim 8, wherein the lever comprises at least one projection which is fitted into the at least first part of the testing device in the output cable-connected and grounded positions of the testing device, thus preventing the rotation of the lever.

10. Testing device according to claim 8, wherein the lever comprises on one of its sides at least one through hole which, in the output cable-connected position of the testing device, allows access to the contacts, and comprising on another one of its sides at least one dead wall which, in the grounded position of the testing device, prevents access to the contacts.

11. Testing device according to claim 8, further comprising an interlocking with the disconnecting switch, such that in the grounded position of the testing device, any operation of the disconnecting switch is prevented when at least one cover of the compartment of the testing device or of the compartment of the cable outlet is open.

12. Testing method for testing cables by means of the testing device described in claim 1, comprising the following steps:
a) opening the contacts of the switch and/or the disconnecting switch;
b) closing the contacts of the disconnecting switch in a grounded position once the absence of voltage in the circuit is verified;
c) opening the cover of the compartment of the testing device or of the compartment of the cable outlet, putting the switch and/or disconnecting switch into service being restricted by interlocking;
d) actuating the testing device from the grounded position to the output-cable connected position;
e) connecting cable testing equipment to the at least one inlet of the testing device; and
f) opening the contacts of the disconnecting switch, said disconnecting switch being located in a position of disconnection.

13. Testing method according to claim 12, further comprising the following steps once cable testing has been performed:
g) grounding the contacts of the disconnecting switch;
h) disconnecting the cable testing equipment from the at least one inlet;
i) actuating the testing device from the output cable-connected position to the grounded position;
j) closing the cover of the compartment of the testing device (6) or of the compartment of the cables, thus releasing the disconnecting switch; and
k) closing the contacts of the switch and/or the disconnecting switch in the position of connection, the electrical equipment thus being operative.
